(19) United States
(12) Patent Application Publication
(10) Pub. No.: US 2007/0120175 A1
(43) Pub. Date: May 31, 2007

(54) EEPROM

(75) Inventor: Kouji Tanaka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 11/601,740

(22) Filed: Nov. 20, 2006

(30) Foreign Application Priority Data
Nov. 29, 2005 (JP) 2005-343039

(51) Int. Cl. H01L 29/788

(52) U.S. Cl. 257/315

(57) ABSTRACT

An EEPROM having a nonvolatile memory cell is provided. The nonvolatile memory cell has: a first well formed in a substrate; a floating gate formed on the substrate through a gate insulating film to overlap a first region of the first well; first and second diffusion layers formed in the first well to contact the first region; and a MOS transistor whose gate electrode is the floating gate and through whose gate insulating film charges are transferred with respect to the floating gate. The first diffusion layer and the second diffusion layer are of opposite conductivity types.

### BACKGROUND OF THE INVENTION

1. Field of the Invention

The present invention relates to a nonvolatile memory, and particularly relates to an EEPROM (Electrically Erasable and Programmable Read Only Memory).

2. Description of the Related Art

An EEPROM is known as a nonvolatile memory capable of electrically programming and erasing data, A “single poly EEPROM” is a type of the EEPROM, which does not have a stacked gate but a single-layer gate. Such a single poly EEPROM is disclosed, for example, in the following patent documents.

In an EEPROM described in Japanese Laid-Open Patent Application JP-P2000-340773, an N+ diffusion layer formed in a surface portion of a semiconductor substrate functions as a control gate. The N+ diffusion layer overlaps a single-layer gate (floating gate) formed on the semiconductor substrate. The single-layer gate also overlaps a tunnel region in the semiconductor substrate, and charges are injected into the single-layer gate from the tunnel region. Furthermore, the EEPROM has a MOS transistor that uses the single-layer gate as a gate electrode. The above-mentioned tunnel region is a part of a source or a drain of the MOS transistor.

An EEPROM described in Japanese Laid-Open Patent Application JP-P2001-185633 has: a first N-well and a second N-well which are formed in a substrate; a single-layer gate (floating gate) formed on the substrate; and a read transistor. The first N-well and the single-layer gate overlap each other through a gate insulating film to form a first capacitor. The second N-well and the single-layer gate overlap each other through a gate insulating film to form a second capacitor. A P-type diffusion layer and an N-type diffusion layer are formed in each of the first and the second N-wells. The P-type diffusion layer is formed around the single-layer gate, while the N-type diffusion layer is formed away from the single-layer gate. Charges are injected into the single-layer gate through the gate insulating film at the first capacitor or the second capacitor.

An EEPROM described in U.S. Pat. No. 6,788,574 has: a first N-well and a second N-well which are formed in a substrate; a single-layer gate (floating gate) formed on the substrate; and a read transistor. The first N-well and the single-layer gate overlap each other through a gate insulating film to form a tunneling capacitor. The second N-well and the single-layer gate overlap each other through a gate insulating film to form a coupling capacitor. A P-type diffusion layer and an N-type diffusion layer are formed in each of the first and the second N-wells. The P-type diffusion layer and the N-type diffusion layer are abutted to each other in each N-well. Charges are injected into the single-layer gate through the gate insulating film at the tunneling capacitor.

Japanese Laid-Open Patent Application JP-H06-334190 discloses a technique in which charges are injected into a single-layer gate through a gate insulating film at not the tunneling capacitor but at a transistor.

FIG. 1 shows a structure of an EEPROM cell described in the Japanese Laid-open Patent Application JP-H06-334190. In FIG. 1, an N-well 104 is formed in a P-type semiconductor substrate 101, and a single-layer polysilicon (floating gate) 108 is formed on the P-type semiconductor substrate 101 through a gate insulating film. An NMOS transistor is formed on the P-type semiconductor substrate 101, while a PMOS transistor is formed on the N-well 104. More specifically, the NMOS transistor consists of N+ diffusion layers (source/drain) 102a, 102b and a gate electrode 103. On the other hand, the PMOS transistor consists of P+ diffusion layers (source/drain) 105a, 105b, an N+ diffusion layer 106 and a gate electrode 107. The above-mentioned single-layer polysilicon (floating gate) 108 is not only the gate electrode 103 of the NMOS transistor but also the gate electrode 107 of the PMOS transistor.

In the EEPROM cell thus constructed, charges are transferred with respect to the floating gate 108 through the gate insulating film of the NMOS transistor, by applying predetermined potentials to respective of terminals 109, 110 and 111. In a programming operation, for example, a high potential Vp is applied to the source/drain 102a, 102b of the NMOS transistor through the terminals 109 and 110, as shown in FIG. 1. on the other hand, a ground potential is applied to the source/drain 105a, 105b and the N+ diffusion layer 106 of the PMOS transistor through the terminal 111. Thus, a high electric field is generated between the floating gate 108 and the source/drain 102a, 102b of the NMOS transistor. As a result, an FN (Fowler-Nordheim) tunneling occurs and hence electrons are ejected from the gate electrode 103 to the source/drain 102a, 102b.

FIG. 2 shows the condition at the time of the above-mentioned programming operation from a viewpoint of capacitance. A gate capacitance of the NMOS transistor is represented by C1, while a gate capacitance of the PMOS transistor is represented by C2. In this case, a potential Vg induced at the floating gate due to capacitive coupling is given by the following equation (1).
vg=C1/(C2+C1)*Vp Eq.(1)

Therefore, a potential difference “Vp−Vg” relating to the FN tunneling in the NMOS transistor is given by the following equation (2).

$$\begin{matrix}Vp - Vg = C 2 / ( C 2 + C 1 ) * Vp \\ = ( 1 / ( 1 + C 1 / C 2 ) ) * Vp \text{:}\end{matrix} \qquad Eq . ( 2 )$$

In the equation (2), the parameter “C1/C2” is called a “capacitance ratio”. For example, when the potential Vp is 10 V and the capacitance ratio C1/C2 is 1/4, the potential difference Vp−Vg should become 8 V. A designer can set the capacitance ratio C1/C2 and the potential Vp such that the potential difference Vp−Vg of a desired value is obtained. As the capacitance ratio C1/C2 is set smaller, the same potential difference Vp−Vg can be obtained with a smaller potential Vp, namely the potential difference Vp−Vg can be generated efficiently. It should be noted here that increase in a difference between the gate capacitances Cl and C2 means that any one of the PMOS transistor and the NMOS transistor becomes extremely large in size. This causes increase in memory cell size, which is unfavorable.

### SUMMARY OF THE INVENTION

The inventor of the present application has first recognized the following points. At the time of the above-mentioned programming operation, the high potential Vp is applied to the NMOS transistor and the ground potential is applied to the PMOS transistor. Therefore, as shown in FIG. 2, an accumulation layer LA is formed in a surface portion of the N-well 104. Negative charges (−) of the accumulation layer LA cause variation of the effective gate capacitance C2 of the PMOS transistor. In a case where a P-well is used instead of the N-well 104, negative charges of an inversion layer cause variation of the effective gate capacitance C2. As a consequence, the potential difference Vp−Vg deviates from a design value. The deviation of the potential difference Vp−Vg from the design value causes variation of programming/erasing characteristics with respect to the memory cell and hence deteriorates reliability of the memory.

In an aspect of the present invention, an EEPROM having a nonvolatile memory cell is provided. The nonvolatile memory cell has: a first well formed in a substrate; a floating gate formed on the substrate through a gate insulating film; and a MOS transistor that uses the floating gate as a gate electrode. The floating gate is formed to overlap a first region of the first well, and the first well serves as a control gate. On the other hand, the MOS transistor serves as a tunneling capacitor, and charges are transferred with respect to the floating gate through a gate insulating film of the MOS transistor. In the first well, a first diffusion layer and a second diffusion layer are so formed as to contact the above-mentioned first region. According to the present invention, the first diffusion layer and the second diffusion layer are of opposite conductivity types and do not form a transistor.

For example, the first well is a P-well. The first diffusion layer is a P+ diffusion layer, while the second diffusion layer is an N+ diffusion layer. At the time of data programming/erasing, a first potential is applied to the P+ diffusion layer and the N+ diffusion layer in the P-well. Also, a second potential different from the first potential by a predetermined potential difference is applied to a diffusion layer of the above-mentioned MOS transistor. As a result, an inversion layer or an accumulation layer is formed in a surface portion of the above-mentioned first region of the P-well, in accordance with the programming operation or the erasing operation.

In the case where the inversion layer is formed, a large number of electrons concentrate in the surface portion of the first region of the P-well, like an N-type semiconductor. In this case, the inversion layer is electrically connected to the N+ diffusion layer according to the present invention, because the N+ diffusion layer is so formed as to contact the first region. As a result, a potential of the inversion layer is fixed at the above-mentioned first potential (predetermined potential). Therefore, the variation of the effective gate capacitance due to the inversion layer is prevented.

On the other hand, in the case where the accumulation layer is formed, a large number of holes concentrate in the surface portion of the first region of the P-well. In this case, the accumulation layer is electrically connected to the P+ diffusion layer according to the present invention, because the P+ diffusion layer is so formed as to contact the first region. As a result, a potential of the accumulation layer is fixed at the above-mentioned first potential (predetermined potential). Therefore, the variation of the effective gate capacitance due to the accumulation layer is prevented.

As described above, the potential of the inversion layer or the accumulation layer is fixed to the predetermined value in either case, because the diffusion layers with the opposite conductivity types are provided to contact the first region. That is to say, the variation of the gate capacitance is prevented in either case of the programming operation or the erasing operation. It is therefore possible to suppress the deviation of the potential difference applied to the gate insulating film of the tunneling capacitor (MOS transistor) from the design value. Since the potential difference is set substantially equal to the design value, variation of programming/erasing characteristics with respect to the memory cell is suppressed and thus reliability of the memory is improved.

According to the nonvolatile memory (EEPROM) of the present invention, the variation of the gate capacitance is prevented in either case of the programming operation or the erasing operation. Since the deviation of the potential difference applied to the gate insulating film of the tunneling capacitor from the design value is suppressed, the variation of programming/erasing characteristics with respect to the memory cell is suppressed.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view schematically showing a structure of a conventional single poly EEPROM;

FIG. 2 is a schematic diagram showing the condition in FIG. 1 from a viewpoint of capacitance;

FIG. 3 is a plan view showing a structure of a nonvolatile memory cell (EEPROM) according to an embodiment of the present invention;

FIG. 4A is a cross-sectional view showing a structure along a line A-A′ in FIG. 3;

FIG. 4B is a cross-sectional view showing a structure along a line B-B′ in FIG. 3;

FIG. 4C is a cross-sectional view showing a structure along a line C-C′ in FIG. 3;

FIG. 5 is a schematic diagram showing a data erasing operation (ERASE) according to the present embodiment;

FIG. 6 is a schematic diagram showing a data programming operation (PROGRAM) according to the present embodiment; and

FIG. 7 is a schematic diagram showing a data read operation (READ) according to the present embodiment.

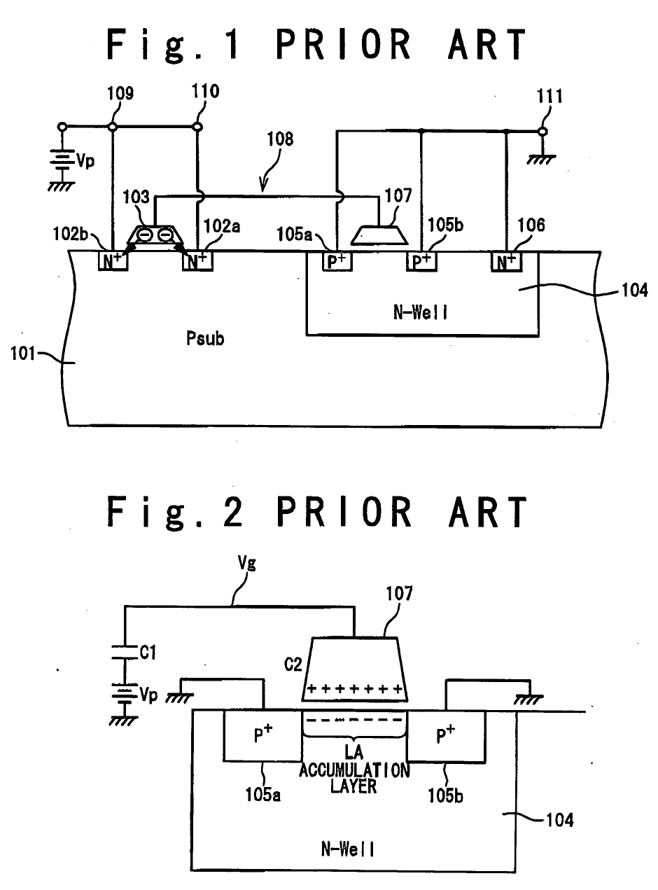

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

A nonvolatile memory according to an embodiment of the present invention will be described below with reference to the attached drawings. The nonvolatile memory according to the embodiment is an EEPROM having a plurality of nonvolatile memory cells.

1. Structure and Principle

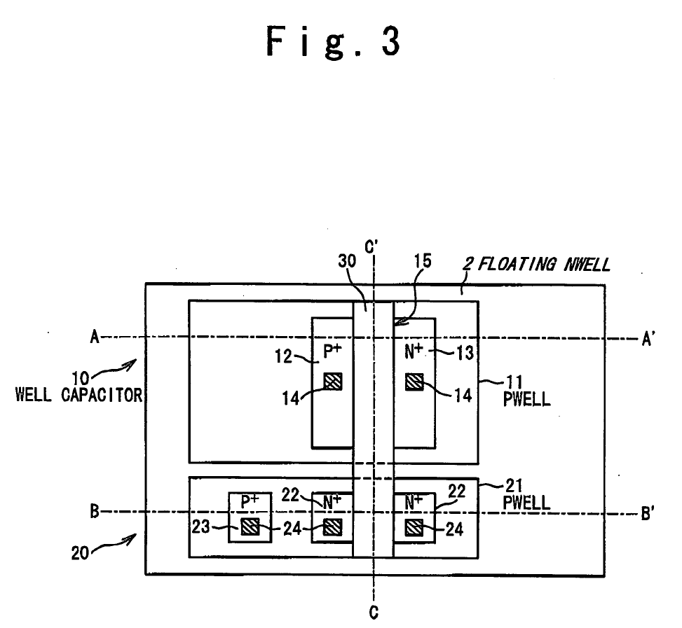

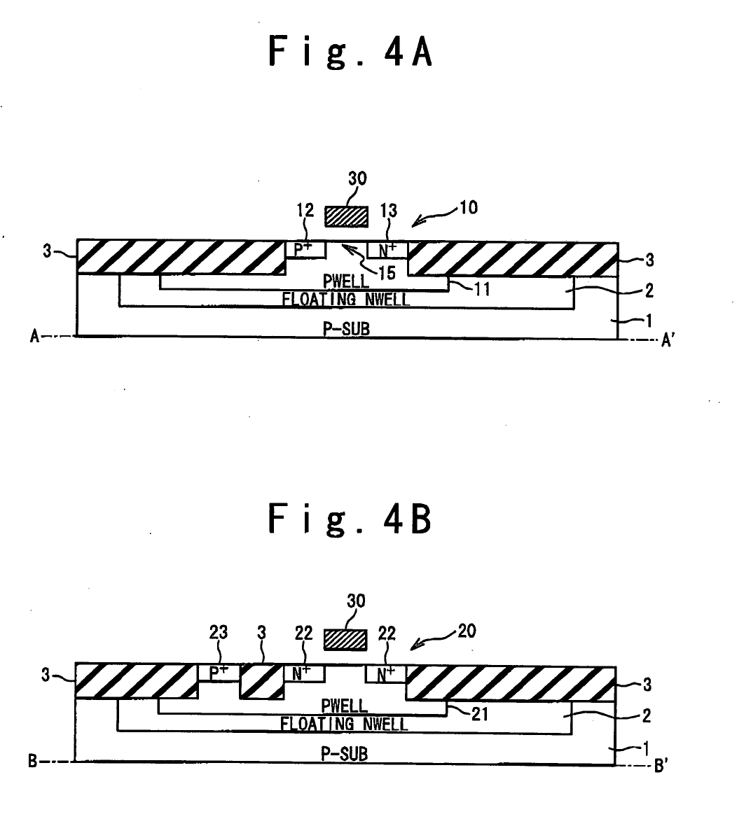

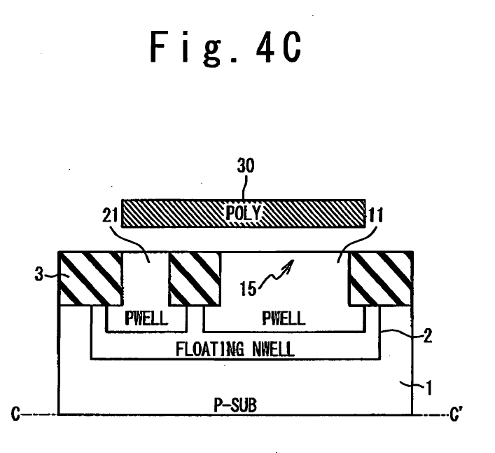

FIG. 3 is a plan view. showing a structure of the nonvolatile memory cell (EEPROM) according to the present embodiment. Cross-sectional structures along a line A-A′, a line B-B′ and a line C-C′ in FIG. 3 are illustrated in FIG. 4A, FIG. 4B and FIG. 4C, respectively.

As shown in FIG. 3, the nonvolatile memory cell according to the present embodiment has a well capacitor 10 and a MOS transistor 20. Furthermore, a floating gate 30 is provided with respect to the well capacitor 10 and the MOS transistor 20.

Referring to FIG. 3, the well capacitor 10 is constituted by a P-well 11 and the floating gate 30. A region in which the floating gate 30 overlaps the P-well 11 is hereinafter referred to as an “overlap region 15”. A P+ diffusion layer 12 and an N+ diffusion layer 13 are so formed in the P-well 11 as to contact the overlap region 15. The P+ diffusion layer 12 and the N+ diffusion layer 13 are formed separately to face each other across the overlap region 15. Moreover, contacts 14 are formed to be connected to the P+ diffusion layer 12 and the N+ diffusion layer 13. FIG. 4A further shows the cross-sectional structure of the well capacitor 10. A device isolation structure 3 is formed in a predetermined region of a surface portion of a P-type substrate 1. A floating N-well 2 is formed in the P-type substrate 1, and the P-well 11 is formed in the floating N-well 2. The floating gate 30 is formed on the P-well 11 through a gate insulating film. The region in which the floating gate 30 overlaps the P-well 11 is the above-mentioned overlap region 15. In the P-well 11, the P+ diffusion layer 12 and the N+ diffusion layer 13 are formed to contact the overlap region 15.

Referring to FIG. 3 again, the MOS transistor 20 is an N-channel MOS transistor formed on a P-well 21. More specifically, N+ diffusion layers 22 as source/drain and a P+ diffusion layer 23 for supplying a well potential are formed in the P-well 21. Contacts 24 are formed to be connected to the N+ diffusion layers 22 and the P+ diffusion layer 23. FIG. 4B further shows the cross-sectional structure of the MOS transistor 20. A device isolation structure 3 is formed in a predetermined region of a surface portion of the P-type substrate 1. A floating N-well 2 is formed in the P-type substrate 1, and the P-well 21 is formed in the floating N-well 2. The N+ diffusion layers (source/drain) 22 and the P+ diffusion layer 23 are formed in the P-well 21. The floating gate 30 is formed on a region sandwiched by the N+ diffusion layers 22 through a gate insulating film. That is, the MOS transistor 20 uses the floating gate 30 as a gate electrode.

FIG. 4C shows the structure of the floating gate 30. The floating gate 30 is so formed as to extend over the P-well 11 and the P-well 21. That is, the floating gate 30 is provided in common with respect to the well capacitor 10 and the MOS transistor 20. Preferably, as shown in FIG. 4C, the floating gate 30 has a single-layer structure. The single-layer floating gate 30 is formed of, for example, a single-layer polysilicon. The floating gate 30 is surrounded by an insulating film and electrically isolated from the surrounding circuitry.

The above-mentioned P-well 11 and the P-well 21 are capacitively coupled to the floating gate 30. In the present embodiment, the P-well 11 of the well capacitor 10 serves as a “control gate”. On the other hand, the charge transfer (charge injection and ejection) with respect to the floating gate 30 occurs through the gate insulating film (tunnel insulating film) of the MOS transistor 20.

The principle of the charge transfer with respect to the floating gate 30 is as follows. A first potential is applied to the P+ diffusion layer 12 and the N+ diffusion layer 13 of the well capacitor 10 through the contacts 14 shown in FIG. 3. Also, a second potential is applied to the N+ diffusion layers 22 and the P-well 21 of the MOS transistor 20 through the contacts 24. The second potential is different from the first potential by a predetermined potential difference, and thus a potential corresponding to the predetermined potential difference is induced at the floating gate 30.

For example, a potential Ve is applied to the P+ diffusion layer 12 and the N+ diffusion layer 13 of the well capacitor 10, while a ground potential GND is applied to the N+ diffusion layers 22 and the P-well 21 of the MOS transistor 20. A capacitance (gate capacitance) between the P-well 11 and the floating gate 30 is represented by C10, while a MOS capacitance of the MOS transistor 20 is represented by C20. In this case, a potential Vg induced at the floating gate 30 due to the capacitive coupling is given by the following equation (3).

$$\begin{matrix}Vg = C 10 / ( C 10 + C 20 ) * Ve \\ = ( 1 / ( 1 + C 20 / C 10 ) ) * Ve \text{:}\end{matrix} \qquad Eq . ( 3 )$$

In the equation (3), the parameter “C20/C10” is called a “capacitance ratio”. The potential difference (voltage) between the potential Vg of the floating gate 30 and the ground potential GND is applied to the gate insulating film of the MOS transistor 20. The FN tunneling occurs due to a strong electric field corresponding to that voltage, and thereby charges are transferred through the gate insulating film of the MOS transistor 20. A designer can set the capacitance ratio C20/C10 and the potential Ve such that the voltage Vg of a desired value is obtained. As the capacitance ratio C20/C10 is set smaller, the same voltage Vg can be obtained with a smaller potential Ve, namely the voltage Vg can be obtained efficiently. It is therefore preferable that an area of the MOS transistor 20 is designed to be smaller than an area of the well capacitor 10 (C10>C20), as shown in FIG. 3.

To read data stored in the above-described nonvolatile memory, the potential state of the floating gate 30 is detected. In order to detect the potential state of the floating gate 30, a transistor (read transistor) is necessary. In the present embodiment, the MOS transistor 20 is used as the read transistor. That is, the MOS transistor 20 according to the present embodiment is necessary for at least data reading and is also used for the charge injection into the floating gate 30.

2. Operations

Next, data programming/erasing/reading operations of the nonvolatile memory cell according to the present embodiment will be described more in detail.

2-1. ERASE (Electron Injection)

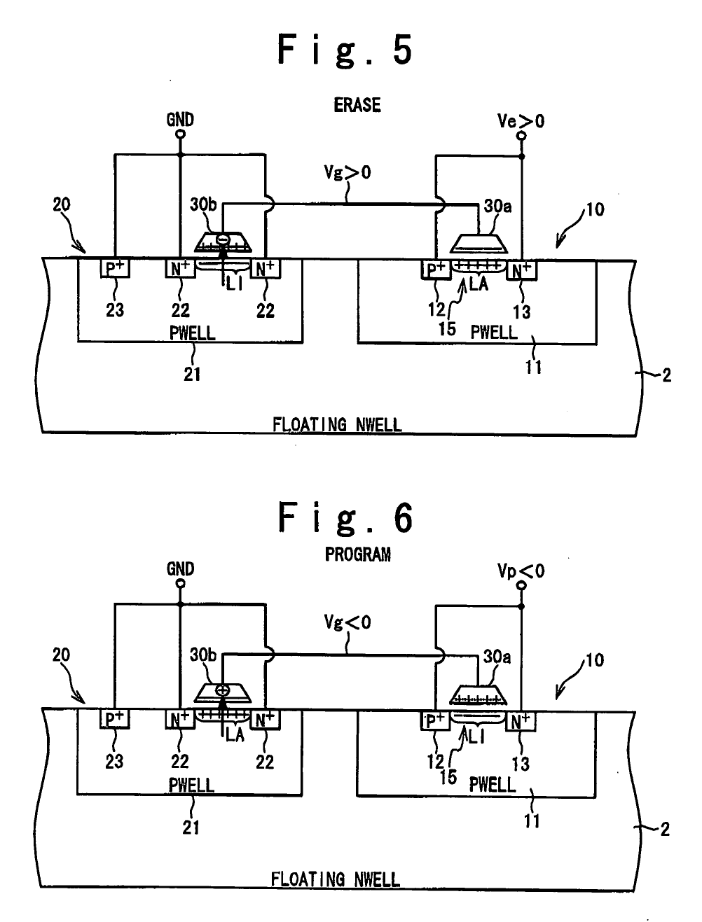

In the erasing operation, electrons are injected into the floating gate 30. FIG. 5 shows an example of a condition of the nonvolatile memory cell at the time of the erasing operation. In FIG. 5, the floating gate 30 is illustrated in such a manner that a gate electrode 30a for the well capacitor 10 and a gate electrode 30b for the MOS transistor 20 are distinguishable from each other. The gate electrode 30a and the gate electrode 30b are electrically connected to each other, and their potentials Vg are the same.

The potentials applied to the P+ diffusion layer 12, the N+ diffusion layer 13, the P-well 21 and the source/drain 22 can be designed appropriately. For example, as shown in FIG. 5, a positive erasing potential Ve is applied to the P+ diffusion layer 12 and the N+ diffusion layer 13 of the well capacitor 10. On the other hand, the ground potential GND is applied to the P-well 21 and the source/drain 22 of the MOS transistor 20. As a result, the potential Vg is induced at the floating gate 30. An electric field corresponding to the potential Vg is applied to the gate insulating film of the MOS transistor 20, and thereby electrons are injected into the floating gate 30.

At the time of the erasing operation, a large number of electrons concentrate in a surface portion of the P-well 21 of the MOS transistor 20 to form an inversion layer LI. On the other hand, a large number of holes concentrate in a surface portion (overlap region 15) of the P-well 11 of the well capacitor 10 to form an accumulation layer LA. According to the present embodiment, since the P+ diffusion layer 12 is so formed as to contact the overlap region 15, the accumulation layer LA is directly connected to the P+ diffusion layer 12 and hence both the layers are electrically connected with each other. As a result, the potential of the accumulation layer LA is fixed at the above-mentioned erasing potential Ve.

When the potential of the accumulation layer LA in which the large number of holes concentrate is fixed, the variation of the effective gate capacitance C10 due to the positive charges (+) in the accumulation layer LA can be prevented. As a result, a difference between the potential Vg actually induced at the floating gate 30 and an expected value expected from the above-described equation (3) is reduced. In other words, the deviation of the potential difference Vg applied to the gate insulating film of the MOS transistor 20 from a design value is suppressed. Therefore, variation of erasing characteristics with respect-to the nonvolatile memory cell is suppressed and thus reliability of the memory is improved.

2-2. PROGRAM (Hole Injection)

In the programming operation, holes are injected into the floating gate 30. FIG. 6 shows an example of a condition of the nonvolatile memory cell at the time of the programming operation in the same manner as in FIG. 5. The potentials applied to the P+ diffusion layer 12, the N+ diffusion layer 13, the P-well 21 and the source/drain 22 can be designed appropriately. For example, as shown in FIG. 6, a negative programming potential Vp is applied to the P+ diffusion layer 12 and the N+ diffusion layer 13 of the well capacitor 10. On the other hand, the ground potential GND is applied to the P-well 21 and the source/drain 22 of the MOS transistor 20. As a result, the potential Vg is induced at the floating gate 30. An electric field corresponding to the potential Vg is applied to the gate insulating film of the MOS transistor 20, and thereby holes are injected into the floating gate 30.

At the time of the programming operation, a large number of holes concentrate in a surface portion of the P-well 21 of the MOS transistor 20 to form an accumulation layer LA. On the other hand, a large number of electrons concentrate in a surface portion (overlap region 15) of the P-well 11 of the well capacitor 10 to form an inversion layer LI. According to the present embodiment, since the N+ diffusion layer 13 is so formed as to contact the overlap region 15, the inversion layer LI is directly connected to the N+ diffusion layer 13 and hence both the layers are electrically connected with each other. As a result, the potential of the inversion layer LI is fixed at the above-mentioned programming potential Vp.

When the potential of the inversion layer LI in which the large number of electrons concentrate is fixed, the variation of the effective gate capacitance C10 due to the negative charges (−) in the inversion layer LI can be prevented. As a result, a difference between the potential Vg actually induced at the floating gate 30 and an expected value expected from the above-described equation (3) is reduced. In other words, the deviation of the potential difference Vg applied to the gate insulating film of the MOS transistor 20 from a design value is suppressed. Therefore, variation of programming characteristics with respect to the nonvolatile memory cell is suppressed and thus reliability of the memory is improved.

2-3. Read

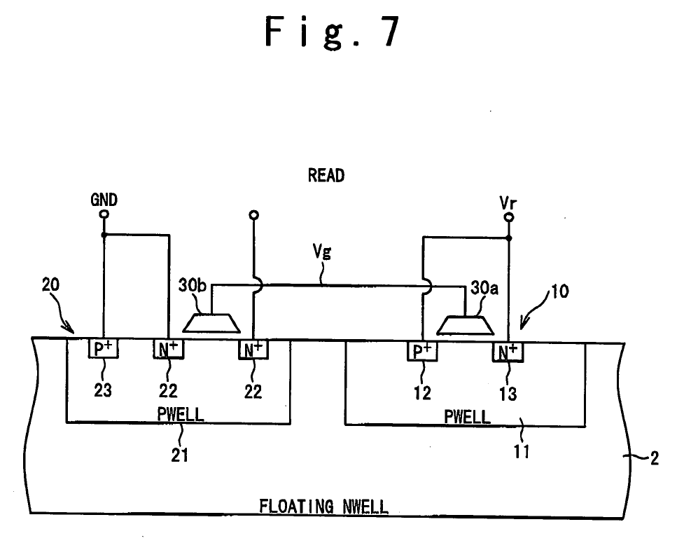

FIG. 7 shows an example of a condition of the nonvolatile memory cell at the time of the reading operation. For example, a read potential Vr is applied to the P+ diffusion layer 12 and the N+ diffusion layer 13 of the well capacitor 10. Furthermore, the ground potential GND is applied to the source 22 and the P-well 21 of the MOS transistor 20, and a predetermined potential is applied to the drain 22 thereof. By detecting whether the MOS transistor 20 is turned ON or not, it is possible to sense a threshold voltage of the MOS transistor 20, namely, the potential state of the floating gate 30 corresponding to the stored data.

3. Effects

According to the present embodiment, the P+ diffusion layer 12 and the N+ diffusion layer 13 which have the opposite conductive types contact the overlap region 15 in the well capacitor 10. Therefore, whether the accumulation layer LA is formed in the overlap region 15 or the inversion layer LI is formed in the overlap region 15, the accumulation layer LA or the inversion layer LI is electrically conducted to any of the P+ diffusion layer 12 and the N+ diffusion layer 13. In other words, the potential of the accumulation layer LA or the inversion layer LI is fixed at the predetermined potential (Ve, Vp) in either case of the programming operation or the erasing operation. As a result, the variation of the effective gate capacitance C10 due to the positive charges (+) in the accumulation layer LA or the negative charges (−) in the inversion layer LI can be prevented. Therefore, the deviation of the potential difference Vg applied to the gate insulating film of the MOS transistor 20 from the design value is suppressed. Since the potential difference Vg is set substantially equal to the design value, the variation of programming/erasing characteristics with respect to the memory cell is suppressed and thus reliability of the memory is improved.

In particular, it is prevented that the potential difference vg applied to the gate insulating film of the MOS transistor 20 becomes greatly smaller than the desired design value, which is preferable. If the potential difference vg becomes greatly smaller than the desired design value, the programming/erasing operations can not be realized in the worst case. It may be considered that the capacitance ratio C20/C10 is designed to be smaller in prospect of the variation of the gate capacitance. However, increase in a difference between the gate capacitances C10 and C20 means that a size of the well capacitor 10 becomes extremely large. This causes an increase in a size of the entire memory cell, which is unfavorable. According to the present embodiment, however, it is not necessary to increase the size of the well capacitor 10 unnecessarily, because the variation of the gate capacitance is suppressed. This is preferable from a viewpoint of the size of the entire memory cell.

Furthermore, the P+ diffusion layer 12 and the N+ diffusion layer 13 are so formed in the P-well 11 as to be separated from each other, as shown in FIG. 3. More specifically, the P+ diffusion layer 12 and the N+ diffusion layer 13 are formed to face each other across the overlap region 15, as in a typical MOS transistor. The P+ diffusion layer 12 and the N+ diffusion layer 13 contact the overlap region 15 over the same length. Such an arrangement is favorable in that the manufacturing process is facilitated.

In addition, the nonvolatile memory cell according to the present embodiment is composed of the two elements (the well capacitor 10 and the MOS transistor 20). As compared with a case of three elements (a tunneling capacitor, a coupling capacitor and a read transistor), the area of the memory cell is reduced, which is preferable.

It is apparent that the present invention is not limited to the above embodiment and may be modified and changed without departing from the scope and spirit of the invention.

What is claimed is:

1. An EEPROM having a nonvolatile memory cell, said nonvolatile memory cell comprising:
a first well formed in a substrate;
a floating gate formed on said substrate through a gate insulating film to overlap a first region of said first well;
first and second diffusion layers formed in said first well to contact said first region; and
a MOS transistor whose gate electrode is said floating gate and through whose gate insulating film charges are transferred with respect to said floating gate,
wherein said first diffusion layer and said second diffusion layer are of opposite conductivity types.

2. The EEPROM according to claim 1,
wherein in data programming and erasing, a first potential is applied to said first diffusion layer and said second diffusion layer in said first well, and a second potential different from said first potential by a predetermined potential difference is applied to a diffusion layer of said MOS transistor.

3. The EEPROM according to claim 2,
wherein a capacitance between said first well and said floating gate is larger than a MOS capacitance of said MOS transistor.

4. The EEPROM according to claim 1,
wherein in data reading, a potential state of said floating gate is detected by using said MOS transistor.

5. The EEPROM according to claim 1,
wherein said first diffusion layer and said second diffusion layer are formed to be separated from each other.

6. The EEPROM according to claim 1,
wherein said first diffusion layer and said second diffusion layer contact said first region over a same length.

7. The EEPROM according to claim 5,
wherein said first diffusion layer and said second diffusion layer are formed to face each other across said first region.

8. The EEPROM according to claim 6,
wherein said first diffusion layer and said second diffusion layer are formed to face each other across said first region.

9. The EEPROM according to claim 1,
wherein said floating gate is formed of a single-layer polysilicon.
